(19) United States
(12) Patent Application Publication
(10) Pub. No.: US 2021/0373685 A1
(43) Pub. Date: Dec. 2, 2021

(54) TOUCH CONTROL STRUCTURE, DISPLAY PANEL, AND DISPLAY DEVICE

(71) Applicant: YUNGU (GU'AN) TECHNOLOGY CO., LTD., Hebei (CN)

(72) Inventors: Yongxin CUI, Kunshan (CN); Xiuqi HUANG, Kunshan (CN); Cheng LIU, Kunshan (CN)

(73) Assignee: YUNGU (GU'AN) TECHNOLOGY CO., LTD., Hebei (CN)

(21) Appl. No.: 17/403,418

(22) Filed: Aug. 16, 2021

Related U.S. Application Data
(63) Continuation of application No. PCT/CN2020/072543, filed on Jan. 16, 2020.

(30) Foreign Application Priority Data
Jun. 28, 2019 (CN) 201910578708.8

(51) Int. Cl. G06F 3/044; G06F 3/041; H01L 27/32

(52) U.S. Cl. CPC G06F 3/044; G06F 3/0412; H01L 51/5253; H01L 27/323; G06F 2203/04102; G06F 3/04164

(57) ABSTRACT

The present disclosure relates to a touch control structure, a display panel, and a display device. The touch control structure includes a substrate, a touch control electrode, and an electrical conducting member. The substrate has a first surface and a plurality of first grooves defined on the first surface. The touch control electrode is disposed on the first surface of the substrate. The electrical conducting member is disposed on the touch control electrode. The touch control electrode is electrically connected to an external circuit via the electrical conducting member. An electrical conducting ability of the electrical conducting member is greater than an electrical conducting ability of the touch control electrode.

### CROSS-REFERENCE TO RELATED APPLICATIONS

This application is a continuation of International Application No. PCT/CN2020/072543, entitled “TOUCH CONTROL STRUCTURE, DISPLAY PANEL, AND DISPLAY DEVICE”, filed on Jan. 16, 2020, which claims priority to Chinese Patent Application No. 201910578708.8, filed on Jun. 28, 2019, both of which are hereby incorporated by reference in their entireties.

### TECHNICAL FIELD

The present disclosure relates to a field of display technology.

### BACKGROUND

An organic light-emitting diode (OLED) display panel, as a light-emitting device of current-driving type, is popular in the market because of its good bendability. A touch control electrode is an important component of a display panel, improving the bendability of the touch control electrode is a key step to manufacture a flexible display panel.

### SUMMARY

In view of this, the present disclosure provides a touch control structure, which includes a substrate, a touch control electrode, and an electrical conducting member. The substrate has a first surface and a plurality of first grooves defined on the first surface. The touch control electrode is disposed on the first surface of the substrate. The electrical conducting member is disposed on the touch control electrode. The touch control electrode is electrically connected to an external circuit via the electrical conducting member. An electrical conducting ability of the electrical conducting member is greater than an electrical conducting ability of the touch control electrode.

The present disclosure also provides a display panel, which includes an organic light-emitting layer and an encapsulation layer covering the light-emitting layer. The display panel also includes the above-mentioned touch control structure. The touch control structure is disposed inside of the encapsulation layer or disposed outside of the encapsulation layer.

The present disclosure also provides a display device, which includes the above-mentioned display panel. The display device can be applied in an electronic device, such as a vehicle-mounted display screen, a mobile phone, or an iPad.

Details of one or more embodiments of the present disclosure are presented in the following drawings and descriptions. Other features, objects and advantages of the present disclosure will become apparent from the description, drawings, and claims.

### BRIEF DESCRIPTION OF THE DRAWINGS

In order to illustrate the embodiments of the present disclosure more clearly, the drawings used in the embodiments will be described briefly. Apparently, the following described drawings are merely schematic views for the embodiments of the present disclosure, and other drawings can be made by those skilled in the art from the accompanying drawings without any inventive effort.

FIG. 1 is a schematic view of a cross section of a touch control structure according to an embodiment of the present disclosure.

FIG. 2 is a schematic view of a cross section of a touch control structure according to another embodiment of the present disclosure.

FIG. 3 is a schematic view of a cross section of a touch control structure according to yet another embodiment of the present disclosure.

FIG. 4 is a schematic view of a cross section of a first groove of a touch control structure according to an embodiment of the present disclosure.

FIG. 5 is a schematic view of a cross section of a touch control structure according to yet another embodiment of the present disclosure.

FIG. 6 is a schematic view of a cross section of a display panel according to an embodiment of the present disclosure.

FIG. 7 is a schematic view of a cross section of a display panel according to another embodiment of the present disclosure.

### DETAILED DESCRIPTION

In order to facilitate understanding of the present disclosure, the present disclosure will be described in detail below with reference to the related drawings. Some embodiments of the present disclosure are shown in the drawings. However, the present disclosure can be implemented in many different forms and not be limited to the embodiments described herein. Rather, the purpose of providing these embodiments is to provide a thorough understanding of the present disclosure.

As described in the background, with continuous development of technology, a flexible OLED electronic device is becoming more and more popular. In order to realize the flexibility of the electronic device, there is a great challenge to a structure of a conventional device. A touch control electrode, which is an important component of a display panel, is configured to sense a contact position between a user's finger (or a stylus) and the display panel. The sensitivity of the touch control electrode is one of the important factors that determine the quality of the display panel. With the development of foldable display panels, the conventional touch control electrode of indium tin oxide (ITO) is gradually unable to meet a performance requirement due to its high cost and poor bending endurance. Moreover, the conventional touch control electrode has problems of poor adhesion, easy detachment, and high electrical resistance. Accordingly, there is a need to provide a new touch control structure, a new display panel, and a new display device.

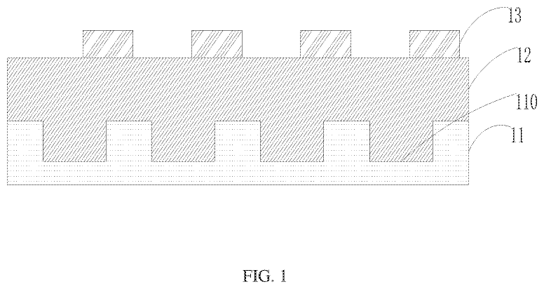

Referring to FIG. 1, an embodiment of the present disclosure provides a touch control structure including a substrate 11, a touch control electrode 12, and an electrical conducting member 13. A plurality of first grooves 110 is defined on an upper surface of the substrate 11. The touch control electrode 12 is disposed on substrate 11 in such a way that the touch control electrode 12 is corresponding to the shape of substrate 11. The electrical conducting member 13 is disposed on the touch control electrode 12. The touch control electrode 12 is electrically connected to an external circuit (not shown) via the electrical conducting member 13. An electrical conducting ability of the electrical conducting member 13 is greater than an electrical conducting ability of the touch control electrode 12.

The above-described touch control structure can be combined with a display member. The touch control structure can be embedded into the display member, or directly disposed on a surface of a encapsulation layer of the display member, or disposed in a module section of the display member, which is not further limited herein.

Since the plurality of first grooves 110 are formed on the upper surface of the substrate 11 of the above-described touch control structure, a contact area between the touch control electrode 12 and the substrate 11 is increased, thereby improving the adhesion between the touch control electrode 12 and the substrate 11. Moreover, the touch control electrode 12 is not easy to detach from the substrate 11 when the substrate 11 is repeatedly bent and deformed.

Optionally, the touch control electrode 12 is a silver electrode. Specifically, the touch control electrode 12 includes a plurality of nanoscale silver particles. The average particle diameter of the nanoscale silver particles ranges from several nanometers (nm) to several hundred nanometers (nm). In an embodiment, the touch control electrode 12 is formed by coating slurry containing the nanoscale silver particles onto the upper surface of the substrate 11 and solidifying the slurry. By controlling the coating thickness of the slurry, the touch control electrode 12 can have good light transmittance. The nanoscale silver particles fill in the first grooves 110 during the coating process. The provision of the plurality of first grooves 110 is particularly conducive to improving the adhesion between the substrate 11 and the touch control electrode 12 which is made of the nanoscale silver particles.

In addition, by providing the electrical conducting member 13 having a greater electrical conducting ability than that of the touch control electrode 12, the electrical conducting ability of the touch control electrode 12 and the external circuit is enhanced, thereby improving the sensitivity of the touch control structure.

Optionally, the substrate 11 is a layer-shaped or plate-shaped structure which is electrically insulative and light transmissive. The substrate 11 can be, but not limited to, a toughened glass substrate. The toughened glass is also called tempered glass with a surface having compressive stresses. The toughened glass is obtained by a tempering method of strengthening the glass. The support ability of the substrate 11 can be improved by using the toughened glass. The substrate of toughened glass can have an ultra-thin thickness, which, for example, ranges from about 100 μm to about 1.1 mm. Therefore, the substrate of toughened glass is balanced between strength and toughness. The substrate 11 can also be, but not limited to, a flexible substrate, such as a substrate of polyimide. The substrate 11 can be a single-layer substrate or a multi-layer substrate including a plurality of laminated layers, which is not further limited herein.

Optionally, the first grooves 110 are provided on the upper surface of the substrate 11. The depth of the first groove 110 can be set according to need, but the first grooves 110 should not extend to reach the lower surface of the substrate 11. This is because once the first grooves 110 reach the lower surface of the substrate 11, the adhesion between the substrate 11 and other members will be dramatically reduced. In other words, the substrate 11 must have a complete surface, such as the lower surface, for adhering to other members. In an embodiment, the depth of the first groove 110 ranges from one third of the thickness of the substrate 11 to one half of the thickness of the substrate 11, so that not only the substrate 11 can have a complete surface, but also the first grooves 110 are able to provide a sufficient space to arrange the touch control electrode 12, thereby increasing a contact area between the touch control electrode 12 and the substrate 11, and ensuring the adhesion between the touch control electrode 12 and the substrate 11.

Optionally, the touch control electrode 12 is disposed on the substrate 11. The touch control electrode 12 is electrically connected to the external circuit (not shown) via the electrical conducting member 13 which is disposed on the touch control electrode 12. The electrical conducting ability of the electrical conducting member 13 can be greater than that of the touch control electrode 12. The touch control electrode 12 is disposed on the substrate 11, that is, a portion of the touch control electrode 12 is embedded into the first groove 110. Compared with a flat contact surface between a substrate and a touch control electrode, due to the provision of the first grooves 110, the contact area between the touch control electrode 12 and the substrate 11 is increased, thereby increasing the adhesion force between the touch control electrode 12 and the substrate 11. In addition, the touch control electrode 12 is electrically connected to the external circuit via the electrical conducting member 13 which has the greater electrical conducting ability, a problem of the high resistance caused by a direct connection between the touch control electrode 12 and the external circuit has been solved. The electrical conducting ability can be represented by electrical resistivity or electrical conductivity. In an embodiment, the electrical resistivity of the touch control electrode 12 is greater than the electrical resistivity of the electrical conducting member 13, and the electrical conductivity of the touch control electrode 12 is smaller than the electrical conductivity of the electrical conducting member 13.

In an embodiment, the touch control electrode 12 also includes a layer-shaped portion disposed on the upper surface of the substrate 11 in addition to the portion of the touch control electrode 12 which is embedded in the first grooves 110. The layer-shaped portion is connected to the portion which is embedded in the first grooves 110, the layer-shaped portion and the portion which is embedded in the first grooves 110 form an integrated touch control electrode 12 which is layer-shaped. In other words, the touch control electrode 12 includes the layer-shaped portion covering the upper surface of the substrate 11 and a plurality of protrusions protruding from the layer-shaped portion into the plurality of first grooves 110 in a one-to-one correspondence. In an embodiment, the protrusions completely fill in the first grooves 110. In an embodiment, the overall thickness of the touch control electrode 12, that is, the distance from the bottom of the first grooves 110 to the upper surface of the touch control electrode 12, can be smaller than 1 mm, for example, ranging from tens of microns to hundreds of microns.

Optionally, the electrical conducting member 13 is a conductive portion which connects the touch control electrode 12 with an signal line of the external circuit. The electrical conducting member 13 has a better electrical conducting ability. The electrical conducting member 13 can be made of a metal material to ensure a good electrical conducting effect.

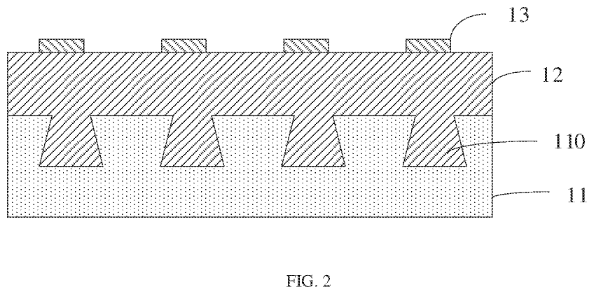

Referring to FIG. 2, in an embodiment, each of at least a number of first grooves 110 has a small end facing to the touch control electrode 12 and a large end being away from the touch control electrode 12. In other words, the first groove 110 has a smaller opening and a larger bottom wall. The larger bottom wall of the first groove 110 increases the contact area between the touch control electrode 12 and the substrate 11, thereby further ensuring the adhesion between the touch control electrode 12 and the substrate 11.

In an embodiment, the cross-sectional area of the small end of the first groove 110 is greater than or equal to one fourth of the cross-sectional area of the bottom wall of the first groove 110, and is smaller than or equal to one half of the cross-sectional area of the bottom wall of the first groove 110. If the opening of the small end of the first groove 110 is too small, the protrusion of the touch control electrode 12 can not completely fill in the first grooves 110 during the production, which reduces the adhesion between the touch control electrode 12 and the substrate 11.

Further, in a thickness direction of the substrate 11, the cross-section of each first groove 110 is shaped as a trapezoidal shape.

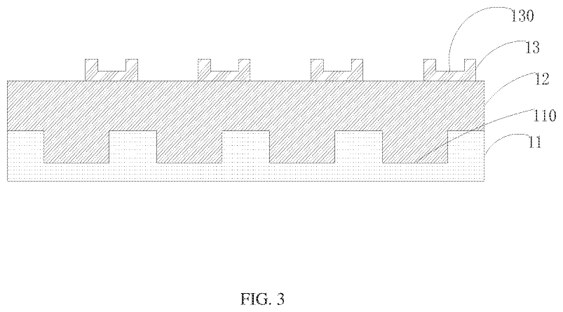

Referring to FIG. 3, in an embodiment, the electrical conducting member 13 includes at least one second groove 130 defined on a surface being away from the touch control electrode 12. The external circuit includes a plurality of signal lines, at least a part of each signal line disposed in the second groove 130. Similarly, the second groove 130 should not extend to a lower surface of the electrical conducting member 13. As mentioned above, the electrical conducting member 13 having a greater electrical conducting ability than the touch control electrode 12 is provided in order to improve the electrical conducting ability of the touch control electrode 12. If the second groove 130 extends to the lower surface of the electrical conducting member 13, an electrode of the external circuit is in direct contact with the touch control electrode 12, the electrical conducting member 13 does not perform a function of conducting electricity, which is contrary to the principle of the present disclosure. Therefore, the second groove 130 should not extend to the lower surface of the electrical conducting member 13. The depth of the second groove 130 can be set according to need. In an embodiment, the depth of the second groove 130 ranges from one third of the thickness of the electrical conducting member 13 to one half of the thickness of the electrical conducting member 13. The signal lines of the external circuit are disposed in the at least one second groove 130 in such a way that the signal line is corresponding to the shape of the second groove of the electrical conducting member 13.

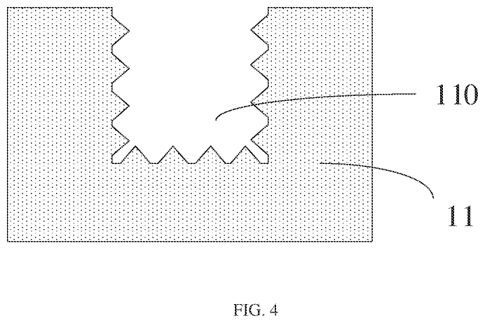

Optionally, each of the first grooves 110 can have at least one uneven wall surface. Optionally, the wall surfaces of the second groove 130 are all flat. Referring to FIG. 4, the wall surface of each of the first grooves 110 can be in a zigzag shape, or the wall surface of each of the first grooves 110 can also include a plurality of protrusions arranged at intervals. The shapes of the wall surfaces of the first grooves 110 can be same or different, which can be decided by those skilled in the art according to need. The at least one uneven surface of the first groove 110 can increase the contact area between the touch control electrode 12 and the substrate 11, thereby increasing the adhesion between the touch control electrode 12 and the substrate 11. The flat surfaces of the second groove 130 can facilitate the arrangement of the signal line of the external circuit, as an uneven surface of the second groove 130 may clamp and break the signal line. In an embodiment, all wall surfaces of each of the first grooves 110 are uneven, and the wall surfaces of the second groove 130 are all flat.

Optionally, an area of an orthographic projection of the electrical conducting member 13 on the substrate 11 is smaller than or equal to an area of an orthographic projection of the touch control electrode 12 on the substrate 11. The provision of the electrical conducting member 13 can enhance the electrical conducting ability between the touch control electrode 12 and the signal line of the external circuit, thereby improving the sensitivity to a touch control signal. An area of the orthographic projection of the touch control electrode 12 on the substrate 11 is greater than or equal to an area of the orthographic projection of the electrical conducting member 13 on the substrate 11, the contact area between the touch control electrode 12 and electrical conducting member 13 is relatively large, thereby improving the sensitivity of the touch control structure to the touch control signal.

Optionally, the electrical conducting ability of the electrical conducting member 13 is greater than the electrical conducting ability of the touch control electrode 12. The electrical conducting member 13 can be made of a metal material, for example, a silver film. The thickness of the silver film ranges from 100 nm to 180 nm.

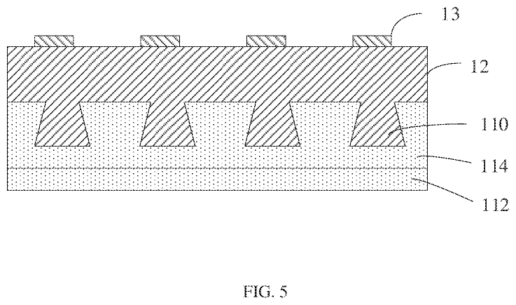

Referring to FIG. 5, in an embodiment, the substrate 11 is a composite substrate, which includes at least a first substrate 112 and a second substrate 114 laminated in sequence. The second substrate 114 is disposed between the first substrate 112 and the touch control electrode 12. The elastic modulus of the first substrate 112 is greater than that of the second substrate 114. The materials of the first substrate 112 and the second substrate 114 can be the same or be different.

In a flexible screen structure, in order to maintain a good bendability of the flexible screen, the elastic modulus of the first substrate 112 can be greater than the elastic modulus of the second substrate 114; that is, the flexibility of the second substrate 114 is greater than the flexibility of the first substrate 112. The first substrate 112 has a degree of rigidity to provide a sufficient support and a flat surface for the formation of subsequent films or layers. The second substrate 114 has a good flexibility and bendability. By using such a composite substrate, not only the flatness of the corresponding surface can be provided during production, but also the flexibility and the bendability of the touch control electrode 12 can be ensured.

In an embodiment, the second substrate 114 is a flexible substrate, for example, a substrate of polyimide.

In an embodiment, the touch control structure includes a plurality of touch control electrodes 12 arranged at intervals. A plurality of electrical conducting members 13 are disposed on each of the plurality of touch control electrodes 12 at intervals.

In an embodiment, the plurality of touch control electrodes 12 are spaced apart at a distance between 20 μm and 30 μm.

In an embodiment, the plurality of electrical conducting members 13 disposed on each touch control electrode 12 are spaced apart at a distance between 1000 μm and 1500 μm.

In an embodiment, the touch control electrode 12 is a touch control electrode of a nanoscale silver wire.

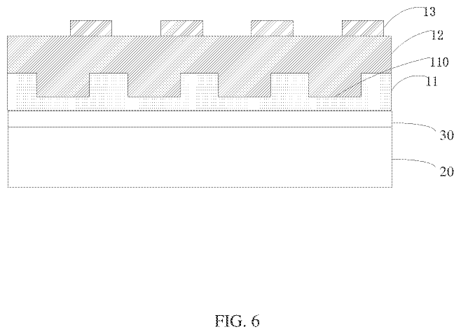

Referring to FIG. 6, in an embodiment of the present disclosure, a display panel is also provided. The display panel includes an organic light-emitting layer 20 and an encapsulation layer 30 covering the organic light-emitting layer 20. The display panel further includes the above-mentioned touch control structure. The touch control structure is disposed inside of the encapsulation layer 30 or disposed outside of the encapsulation layer 30.

Optionally, the touch control structure is in contact with an upper surface of the encapsulation layer 30.

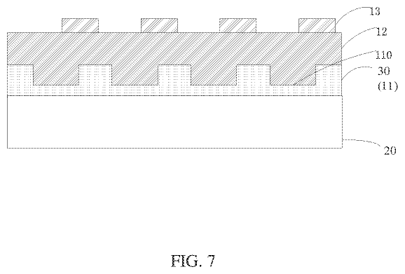

Optionally, the encapsulation layer 30 is a thin film encapsulation structure. Referring to FIG. 7, the thin film encapsulation structure can be used as the substrate 11 of the touch control structure, and there is no need to additionally provide the substrate 11, thereby reducing the thickness of the display panel and improving the bendability of the display panel.

Optionally, the thin film encapsulation structure includes a first inorganic encapsulation layer, an organic encapsulation layer, and a second inorganic encapsulation layer which are laminated in sequence. Such a thin film encapsulation structure is capable of preventing water and oxygen from damaging the organic light-emitting material layer, thereby prolonging the service life of the display panel.

The display panel of the present disclosure can be an active-matrix organic light-emitting diode (AMOLED) display panel, a micro-OLED display panel, or a quantum dot display panel. The display panel can also be applied to various display devices, such as a smartphone, a tablet computer, an vehicle-mounted display device, a wearable display device, and the like.

In the present disclosure, when describing a positional relationship, unless otherwise described, when a member such as a layer, a film, or a substrate is disposed “on” another film or layer, it should be interpreted that either the layer, the film, or the substrate is in contact with the other film or layer, or there is an intermediate film layer therebetween. Further, when a layer is disposed “under” or “below” another layer, it should be interpreted that the layer is disposed beneath another layer, or there is one or more intermediate films or layers therebetween. It should also be understood that when describing a layer which is disposed “between” two layers, it should be interpreted that either the only layer is disposed between the two layers, or there is one or more intermediate layers therebetween. In the present disclosure, when describing a positional relationship, the terms “on”, “under” are based on an orientational relationship or positional relationship shown in the drawings and are used for simplifying the description. These terms do not indicate or imply that a member or a device must be arranged “on” or “under” another member or device, and are not intended to limit the scope of the present disclosure.

In the present disclosure, when using the terms “include”, “have”, and “comprise”, unless the terms are modified by other specific limiting terms such as “only”, “merely”, an additional element can be involved. The singular form of a term can cover the meaning of a plural form of the term and, unless expressly specified otherwise, cannot be interpreted that the number of the term is one.

The technical features of the above-mentioned embodiments may be arbitrarily combined. In order to make the description simple, not all possible combinations of the technical features in the above embodiments are described. However, as long as there is no contradiction in the combination of these technical features, the combinations should be in the scope of the present disclosure.

What described above are only several implementations of the present disclosure, and these embodiments are specific and detailed, but not intended to limit the scope of the present disclosure. It should be understood by the skilled in the art that various modifications and improvements can be made without departing from the conception of the present disclosure, and all fall within the protection scope of the present disclosure. Therefore, the patent protection scope of the present disclosure is defined by the appended claims.

What is claimed is:

1. A touch control structure, comprising:
a substrate having a first surface and a plurality of first grooves defined on the first surface;
a touch control electrode disposed on the first surface of the substrate; and
an electrical conducting member disposed on the touch control electrode;
wherein the touch control electrode is electrically connected to an external circuit via the electrical conducting member, and an electrical conducting ability of the electrical conducting member is greater than an electrical conducting ability of the touch control electrode.

2. The touch control structure according to claim 1, wherein the touch control electrode is a silver electrode.

3. The touch control structure according to claim 1, wherein a depth of each of the plurality of first grooves is in a range from one third of a thickness of the substrate to one half of a thickness of the substrate.

4. The touch control structure according to claim 1, wherein each of the plurality of first grooves has at least one uneven wall surface.

5. The touch control structure according to claim 1, wherein at least one of the plurality of first grooves has a small end facing the touch control electrode and a large end being away from the touch control electrode, an area of the small end of the first groove is smaller than an area of the large end of the first groove.

6. The touch control structure according to claim 1, wherein in a thickness direction of the substrate, a cross-section of each of the plurality of first grooves is shaped as a trapezoidal shape.

7. The touch control structure according to claim 1, wherein at least one second groove is defined on a surface of the electrical conducting member, and the surface of the electrical conducting member is away from the touch control electrode.

8. The touch control structure according to claim 7, wherein a depth of the second groove is in a range from one third of a thickness of the electrical conducting member to one half of a thickness of the electrical conducting member.

9. The touch control structure according to claim 7, wherein a plurality of wall surfaces of the second groove are all flat.

10. The touch control structure according to claim 7, wherein the external circuit comprises a plurality of signal lines, at least a part of the signal line is disposed in the second groove.

11. The touch control structure according to claim 1, wherein an area of an orthographic projection of the electrical conducting member on the substrate is smaller than or equal to an area of an orthographic projection of the touch control electrode on the substrate.

12. The touch control structure according to claim 1, wherein a material of the electrical conducting member is metal.

13. The touch control structure according to claim 1, wherein the substrate is a composite substrate, and the substrate comprises at least a first substrate and a second substrate laminated with each other; and the second substrate is disposed between the first substrate and the touch control electrode; and an elastic modulus of the first substrate is greater than an elastic modulus of the second substrate; and the plurality of first grooves are defined on a surface of the second substrate, and the surface of the second substrate is away from the first substrate.

14. The touch control structure according to claim 13, wherein the second substrate is a flexible substrate.

15. The touch control structure according to claim 1, wherein the touch control structure comprises a plurality of touch control electrodes, and the plurality of touch control electrodes are disposed on the first surface of the substrate at intervals.

16. The touch control structure according to claim 15, wherein the touch control structure comprises a plurality of electrical conducting members, and the plurality of electrical conducting members are disposed on each of the plurality of touch control electrodes at intervals.

17. The touch control structure according to claim 1, wherein the touch control electrode comprises a layer-shaped portion covering the first surface of the substrate and a plurality of protrusions protruding from the layer-shaped portion into the plurality of first grooves in a one-to-one correspondence.

18. A display panel, comprising an organic light-emitting layer, an encapsulation layer covering the organic light-emitting layer, and the touch control structure according to claim 1, wherein the touch control structure is disposed inside of the encapsulation layer or disposed outside of the encapsulation layer.

19. A display device, comprising the display panel according to claim 18.
